(19) United States
(12) Patent Application Publication
(10) Pub. No.: US 2012/0288966 A1
(43) Pub. Date: Nov. 15, 2012

(54) METHOD FOR DECAPSULATING INTEGRATED CIRCUIT PACKAGE

(76) Inventors: Ming-Teng Hsieh, New Taipei City (TW); Yi-Nan Chen, Taipei City (TW); Hsien-Wen Liu, Taoyuan County (TW)

(21) Appl. No.: 13/105,905

(22) Filed: May 12, 2011

(51) Int. Cl. H01L 21/30; H01L 21/306

(52) U.S. Cl. 438/4; 438/745; 257/E21.219; 257/E21.211

(57) ABSTRACT

A method for decapsulating an integrated circuit package in the absence of a mask is disclosed. First, a package is provided. The package includes at least a circuit element and a molding compound enclosing the circuit. Second, a caustic solution is simultaneously provided and drained. The caustic solution is capable of etching the molding compound while in continuous contact with the molding compound to etch the molding compound. As a consequence, the molding compound is removed so that the circuit element in the package is substantially exposed.

### BACKGROUND OF THE INVENTION

1. Field of the Invention

The present invention generally relates to a method for decapsulating an integrated circuit package. In particular, the present invention generally relates to a method for decapsulating an integrated circuit package to expose a target integrated circuit therein without substantially damaging the target integrated circuit.

2. Description of the Prior Art

After an integrated circuit is manufactured, the integrated circuit needs packaging to keep it from damages caused by ambient conditions. Once an integrated circuit chip or die is encapsulated by a molding compound or encapsulant to form an integrated circuit package, it is difficult to decapsulate the package without damaging the integrated circuit inside.

FIG. 1 illustrates a typical method to open a package in order to expose the integrated circuit therein. As shown in FIG. 1, the entire integrated circuit package 10 is dipped in a corrosive solution 20, which is usually a strong acid, which etches the organic encapsulant 11 to expose the integrated circuit 12 such as interconnected elements. However, once the integrated circuit 12 is exposed, it is almost impossible to quench the etching reaction so the integrated circuit 12 is almost always resultantly and seriously damaged.

Another approach is to put some corrosive solution 20 on the integrated circuit package 10 to etch the organic encapsulant 11. In order to avoid some undesirable side etching, a mask 13 is usually employed to cover a peripheral area of the integrated circuit package 10 and only the integrated circuit package 10 exposed is etched. In spite of the protection of the mask 13, undesirable over-etching still occurs so the integrated circuit 12 is still inevitably damaged. When the damaged integrated circuit 12 is subjected to a later test, such as a circuit edit or a repair procedure, the damaged integrated circuit 12 is often useless.

### SUMMARY OF THE INVENTION

The present invention therefore proposes a novel method for decapsulating an integrated circuit package without the need of using a mask during the decapsulation process. The method of the present invention is capable of removing the outer organic molding compound and exposing the integrated circuit therein without substantially damaging the integrated circuit.

First, a package is provided. The package includes at least a circuit element and a molding compound enclosing the circuit. Second, a caustic solution is simultaneously provided and drained. The caustic solution is capable of etching the molding compound while in continuous contact with the molding compound to etch the molding compound. As a consequence, the molding compound is removed so that the circuit element in the package is substantially exposed.

In one embodiment of the present invention, the caustic solution includes an acid.

In another embodiment of the present invention, the acid has a raised temperature.

In another embodiment of the present invention, the acid includes nitric acid.

In another embodiment of the present invention, the acid further includes sulfuric acid.

In another embodiment of the present invention, the circuit element includes an Al/Au alloy.

In another embodiment of the present invention, the molding compound is removed in the absence of an etching mask.

In another embodiment of the present invention, the molding compound is removed in the presence of a monitor.

In another embodiment of the present invention, the caustic solution is provided by a dropper.

In another embodiment of the present invention, a suction device is provided providing to drain the caustic solution when the molding compound is being removed.

In another embodiment of the present invention, the package is placed on a stage with a changeable position.

In another embodiment of the present invention, the molding compound is removed so that the package is partially de-capped.

In another embodiment of the present invention, the package is rinsed by a cleaning solution.

In another embodiment of the present invention, the package is rinsed before the molding compound is removed.

In another embodiment of the present invention, the package is rinsed after the molding compound is removed.

In another embodiment of the present invention, the cleaning solution includes deionised water.

In another embodiment of the present invention, the cleaning solution includes acetone.

In another embodiment of the present invention, the circuit element is further processed.

In another embodiment of the present invention, the circuit element is further processed by means of a circuit edit.

In another embodiment of the present invention, the circuit edit is carried out by using a focused ion beam (FIB).

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates a conventional method to open a package in order to expose the integrated circuit.

FIG. 2 illustrates another conventional method to open a package in order to expose the integrated circuit.

FIGS. 3-8 illustrate the method for decapsulating an integrated circuit package of the present invention.

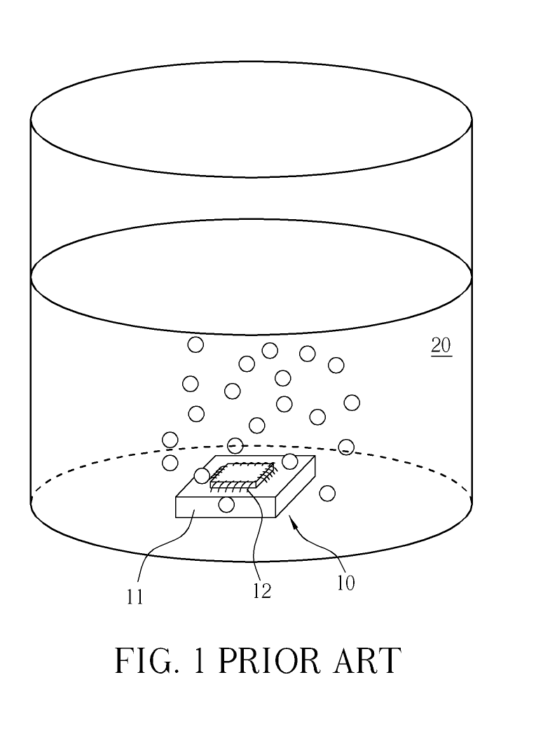

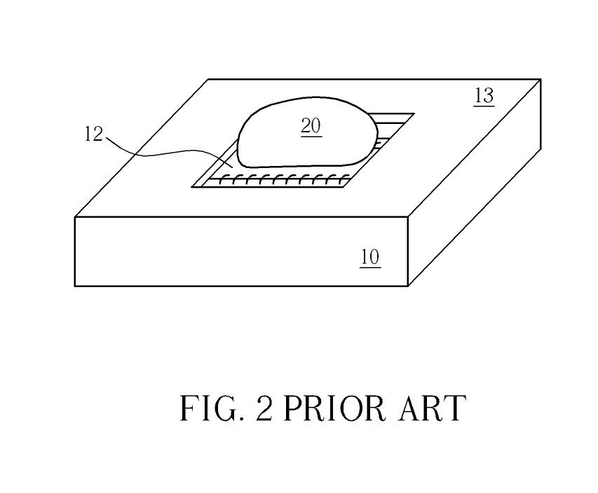

### DETAILED DESCRIPTION

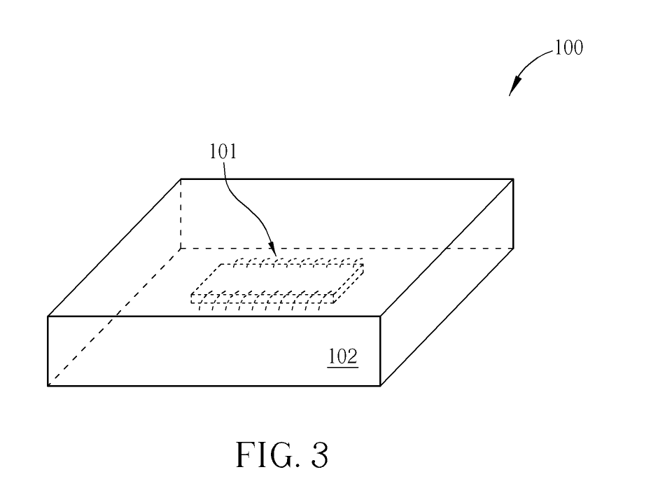

The present invention provides a method for decapsulating an integrated circuit package in the absence of a mask without substantially damaging the circuit element to be revealed inside the integrated circuit chip or die. Please refer to FIGS. 3-8, which illustrate the method of the present invention for decapsulating an integrated circuit package. As shown in FIG. 3, a package 100 is provided. The package 100 is usually an integrated circuit chip package. The package 100 includes at least a circuit element 101 and a molding compound 102. The molding compound 102 is used to enclose the circuit element 101 and to protect it from an ambient condition. The circuit element 101 may include an interconnection structure including a metal or an alloy, such as an Al/Au alloy, or may include any elements of the integrated circuit. The molding compound 102 may include an organic compound, such as an epoxy resin.

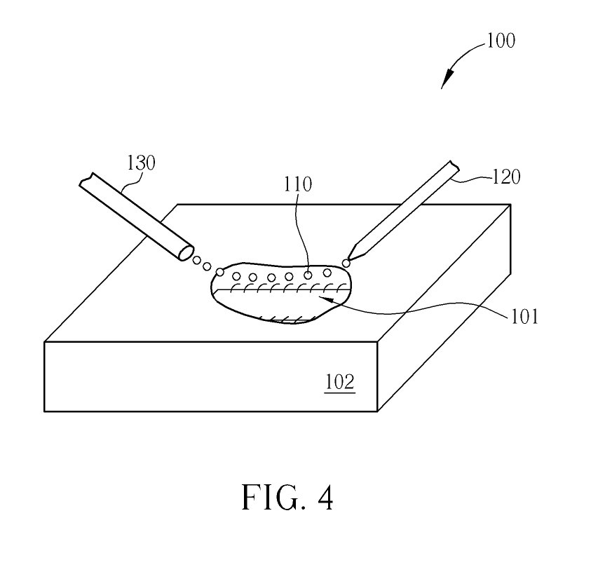

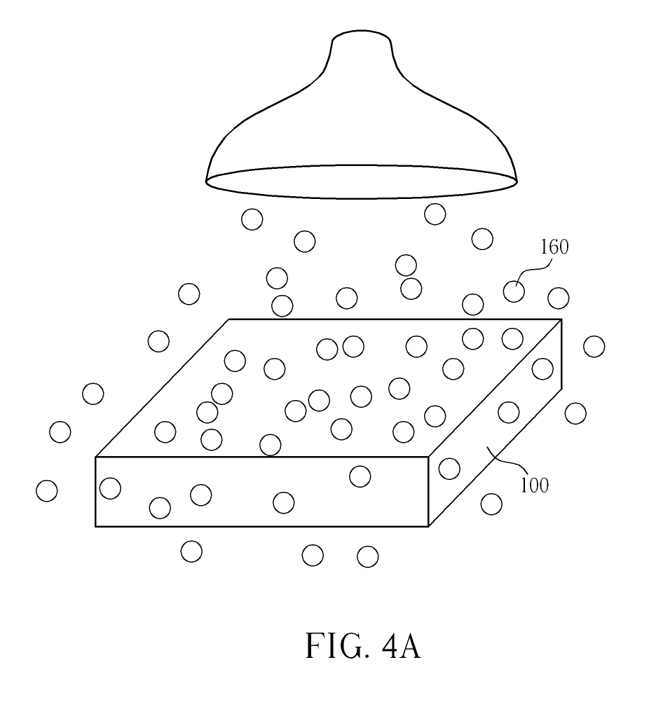

As shown in FIG. 4, a caustic solution 110 is provided. The caustic solution 110 is capable of etching the molding compound 102.

In one embodiment of the present invention, the caustic solution 110 may contain an acid, for example nitric acid. The caustic solution 110 may further contain another different acid, for example sulfuric acid, so the caustic solution 110 may be a mixed acid. In another embodiment of the present invention, the acid may have a raised temperature, for example heated, to accelerate the chemical reaction. Optionally, as shown in FIG. 4A, in another embodiment of the present invention, the package 100 may be well rinsed by a cleaning solution 160 before subjected to the next step, for example an etching step to clean the surface of the package 100.

One feature of the present invention resides in that the caustic solution 110 is simultaneously drained while the caustic solution 110 is in continuous contact with the molding compound 102 as it etches the molding compound 102. Since there is always not too much caustic solution 110 in continuous contact with the molding compound 102, the etching of the molding compound 102 may be carried out in the absence of an etching mask and as a result a procedure to strip the etching mask can be omitted after the etching of the molding compound 102 is done.

For example, as shown in FIG. 4, the caustic solution 110 is continuously provided by a dropper 120 to etch the molding compound 102 while the caustic solution 110 is also continuously drained by a suction device 130 nearby to carefully control the etching rate. The flow rate of the caustic solution 110 or the suction rate of the suction device 130 is optional as long as there is always enough caustic solution 110 flowing to etching the molding compound 102.

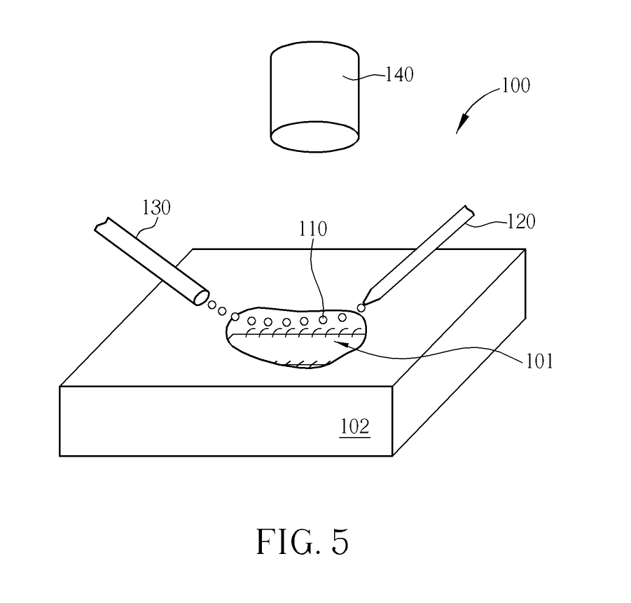

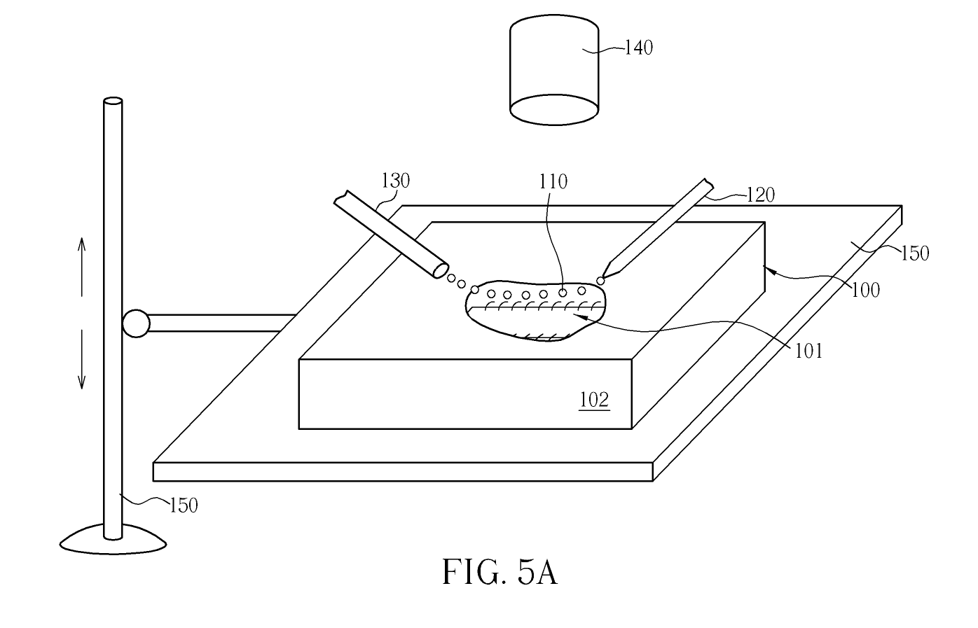

In another embodiment of the present invention, as shown in FIG. 5, there may be a monitor 140 provided for constantly following up the progress of the etching procedure when an auxiliary device is needed. In still another embodiment of the present invention, as shown in FIG. 5A, the package 100 may be placed on a stage, such as a platform 150, with a changeable position. The position of the platform 150 is adjustable to facilitate the practice of the present invention.

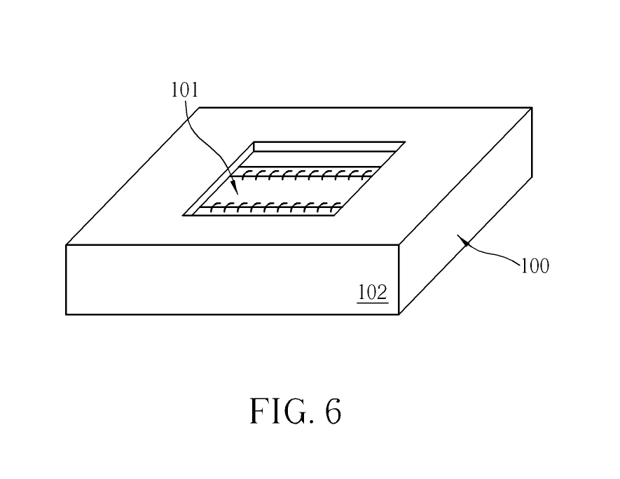

After a period of time, as shown in FIG. 6, the molding compound 102 is adequately removed so that the package 100 is partially de-capped and the circuit element 101 within the package 100 is substantially exposed. Because the etching rate can be well controlled and adjusted by the previously mentioned embodiments, the molding compound 102 can be adequately removed and at the same time the integrated circuit element 101 therein is not substantially damaged for further purposes.

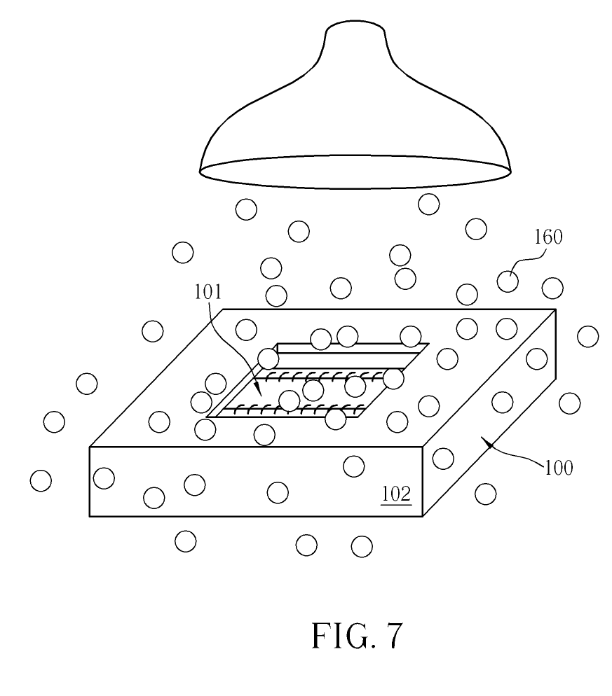

If the etching procedure should be quenched, in another embodiment of the present invention, the package 100 may be rinsed by a cleaning solution 160 after the etching procedure, as shown in FIG. 7. The cleaning solution 160 may include deionized water, or the cleaning solution 160 may further include acetone so the cleaning solution 160 may be a mixed solution.

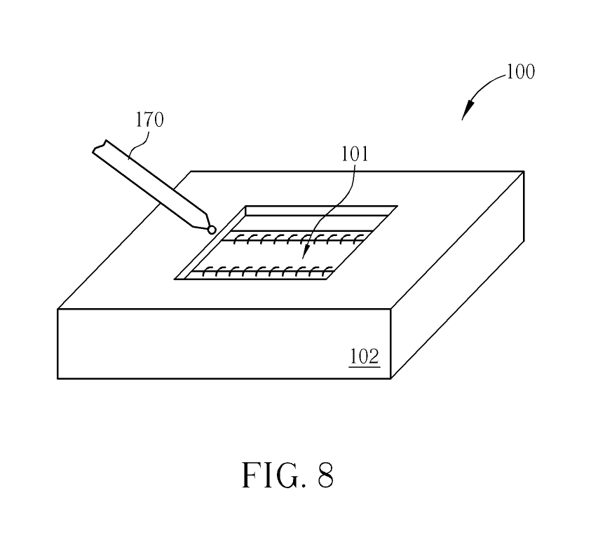

Because the circuit element 101 is exposed and not substantially damaged, the circuit element 101 may further processed. For example, as shown in FIG. 8, the circuit element 101 is subjected to a processing device 170, such as for circuit editing. The circuit edit may be carried out by using a focused ion beam (FIB). Generally speaking, the FIB editor may be used to adjust the circuit element 101. For example, the FIB editor may be used to change a DDR2 to a DDR 3, to change the ESD circuit, to accelerate, to solve a current problem, to speed up the verification of the function of a new reticle or to speed up the mass manufacture.

Those skilled in the art will readily observe that numerous modifications and alterations of the device and method may be made while retaining the teachings of the invention.

1. A method for decapsulating an integrated circuit package, comprising:
providing a package comprising a circuit element and a molding compound enclosing said circuit;
providing and draining a caustic solution which is capable of etching said molding compound in continuous contact with said molding compound to etch said molding compound; and
removing said molding compound in the absence of an etching mask so that said circuit element in said package is substantially exposed.

2. The method for decapsulating an integrated circuit package of claim 1, wherein said molding compound comprises an epoxy resin.

3. The method for decapsulating an integrated circuit package of claim 1, wherein said caustic solution comprises an acid.

4. The method for decapsulating an integrated circuit package of claim 1, wherein said acid has a raised temperature.

5. The method for decapsulating an integrated circuit package of claim 3, wherein said acid comprises nitric acid.

6. The method for decapsulating an integrated circuit package of claim 3, wherein said acid comprises sulfuric acid.

7. The method for decapsulating an integrated circuit package of claim 1, wherein said circuit element comprises an Al/Au alloy.

8. The method for decapsulating an integrated circuit package of claim 1, wherein removing said molding compound is carried out in the absence of an etching mask.

9. The method for decapsulating an integrated circuit package of claim 1, wherein removing said molding compound is carried out in the presence of a monitor.

10. The method for decapsulating an integrated circuit package of claim 1, wherein said caustic solution is provided by a dropper.

11. The method for decapsulating an integrated circuit package of claim 1, further comprising:
providing a suction device to drain said caustic solution when removing said molding compound is carried out.

12. The method for decapsulating an integrated circuit package of claim 1, wherein said package is placed on a stage with a changeable position.

13. The method for decapsulating an integrated circuit package of claim 1, wherein removing said molding compound is carried out so that said package is partially de-capped.

14. The method for decapsulating an integrated circuit package of claim 1, further comprising:
rinsing said package by a cleaning solution.

15. The method for decapsulating an integrated circuit package of claim 14, wherein rinsing said package before removing said molding compound.

16. The method for decapsulating an integrated circuit package of claim 14, wherein rinsing said package after removing said molding compound.

17. The method for decapsulating an integrated circuit package of claim 14, wherein said cleaning solution comprises deionised water.

18. The method for decapsulating an integrated circuit package of claim 14, wherein said cleaning solution comprises acetone.

19. The method for decapsulating an integrated circuit package of claim 1, further comprising:
processing said circuit.

20. The method for decapsulating an integrated circuit package of claim 19, wherein processing said circuit element comprises a circuit edit.

21. The method for decapsulating an integrated circuit package of claim 20, wherein said circuit edit is performed by using a focused ion beam (FIB).
